(19) United States
(12) Patent Application Publication
(10) Pub. No.: US 2021/0213448 A1
(43) Pub. Date: Jul. 15, 2021

(54) NANO-PATTERNED SURFACES FOR MICROFLUIDIC DEVICES AND METHODS FOR MANUFACTURING THE SAME

(71) Applicant: CORNING INCORPORATED, CORNING, NY (US)

(72) Inventors: Donald Erwin Allen, Painted Post, NY (US); Ye Fang, Painted Post, NY (US); Wei Jiang, Vestal, NY (US); Jeffrey Glenn Lynn, Wellsboro, PA (US); Barry James Paddock, Horseheads, NY (US); Ying Zhang, Horseheads, NY (US)

(21) Appl. No.: 17/251,016

(22) PCT Filed: Jun. 10, 2019
(86) PCT No.: PCT/US2019/036354

§ 371 Date: Dec. 10, 2020

Related U.S. Application Data
(60) Provisional application No. 62/685,105, filed on Jun. 14, 2018.

(51) Int. Cl. B01L 3/00; B81B 1/00; B81C 1/00

(52) U.S. Cl. CPC B01L 3/502707; B81B 1/002; B81C 1/00063; B01L 2200/12; B01L 2300/0896; B81C 2203/032; B01L 2300/168; B81B 2201/057; B81B 2203/033; B81C 2201/0132; B81C 2201/0153; B01L 2300/0887

(57) ABSTRACT

A method of making a microfluidic device (200, 201, 300) can include depositing a layer of photoresist onto a first substrate (210, 270, 310), selectively removing the photoresist to expose portions of the first substrate (210, 270, 310), etching the exposed portions of the first substrate (210, 270, 310) to form an array of nano-wells (240, 340), coating each nano-well (240, 340) with metal oxide, and coating the metal oxide on each nano-well (240, 340) with a first material to increase binding of DNA, proteins, and polynucleotides to the metal oxide. A layer of a second material can be deposited on interstitial areas between the nano-wells (240, 340) to inhibit binding of DNA, proteins, and polynucleotides to the interstitial areas. A second substrate (220, 320) can be bonded to the first substrate (210, 270, 310) to enclose the array of nano-wells (240, 340) in a cavity.

### CROSS-REFERENCE TO RELATED APPLICATIONS

This application claims the benefit of priority under 35 U.S.C. § 119 of U.S. Provisional Application No. 62/685,105, filed Jun. 14, 2018, the content of which is incorporated herein by reference in its entirety.

### FIELD

The present disclosure generally relates to patterned microfluidic devices and methods of manufacturing patterned microfluidic devices for biomolecular analysis, and in particular, gene sequencing.

### BACKGROUND

Biological samples are often complicated in composition and amount. Analysis of biomolecules in a biological sample often involves partitioning a sample into tens of thousands or millions of samples for quantitative determination. Many different partitioning methods have been developed, including surface patterning (including surface chemistry and structure patterning), micro-droplets, continuous or discontinuous flow, and separation under physical force (e.g., electrophoresis). Among them, surface patterning is one of the most effective means to selectively capture and partition biomolecules in a biological sample for bioanalysis. Furthermore, owing to its ability to spatially and/or temporally control bio-reactions, microfluidics has been combined with surface patterning to achieve high sensitivity and specificity for biomolecular analysis. For instance, for optical detection based massively parallel gene sequencing applications, millions of short DNA fragments generated from a genomic DNA sample can be captured and partitioned onto a patterned surface of a microfluidic device such that these DNA fragments are spatially separated from each other to facilitate sequencing by, for example, synthesis, ligation, or single-molecule real-time imaging. These gene sequencing techniques can be used to sequence entire genome, or small portions of the genome such as the exome or a pre selected subset of genes.

A variety of massively parallel gene sequencing techniques can be divergent in DNA immobilization chemistry, clustering, and DNA sequencing principles. For instance, for sequencing by synthesis based on bridge amplification or template walking, DNA molecules can be covalently captured and partitioned onto a flat substrate having a polymeric hydrogel coating or a short linker molecule, respectively. For sequencing by synthesis based on exclusion amplification, DNA molecules can be selectively captured and partitioned on a patterned nano-well substrate having a polymeric hydrogel coating. For sequencing by ligation, DNA nanoballs generated via a rolling circle replication amplification can be electrostatically captured onto a patterned positively charged surface (e.g., amine silane coated surface). For sequencing by synthesis based on single molecule detection, DNA molecule s can be covalently attached to a surface.

Embodiments of the present disclosure represent an advancement over the state of the art with respect to microfluidic devices and methods of making same. These and other advantages, as well as additional inventive features, will be apparent from the description provided herein.

### SUMMARY

Embodiments of the present disclosure disclose systems and methods related to patterned microfluidic devices having a surface containing regions that promote binding to DNA, proteins, and/or nucleotides, and regions that inhibit binding to DNA, proteins, and/or nucleotides. Some embodiments of the disclosure relate to the manufacturing process used to make the aforementioned patterned microfluidic devices. The uses for these patterned microfluidic devices include, among other things, DNA sequencing applications.

In some embodiments, the disclosed patterned microfluidic devices have a surface including two distinct chemistries, one promoting DNA binding, and another inhibiting DNA binding. This enables selective binding and partitioning of DNA fragments onto the surface. Such patterned microfluidic devices having a surface including two distinct chemistries allows for a relatively high signal-to-noise ratio when detecting DNA molecules and determining DNA sequencing. Furthermore, using two distinct chemistries, as described herein, can provide enhancement of fluorescence imaging via confinement of DNA molecules inside dielectric coated nano-wells.

Some embodiments of the present disclosure provide a method of making a microfluidic device. The method can include the steps of depositing a layer of photoresist onto a first substrate, selectively removing the photoresist to expose portions of the first substrate under the photoresist layer, and etching the exposed portions of the first substrate to form an array of nano-wells. The method further can include depositing a metal oxide layer over the photoresist such that each nano-well in the array of nano-wells is coated with metal oxide, and depositing a layer of a first material such that each nano-well in the array of nano-wells is coated with the first material. The first material can be configured to increase binding of DNA, proteins, and/or polynucleotides to the metal oxide. The method also can include depositing a layer of a second material on interstitial areas between the nano-wells. The second material can be configured to inhibit the binding of DNA, proteins, and/or polynucleotides to the interstitial areas. The method also can include bonding a second substrate to the first substrate to enclose the array of nano-wells in a cavity formed between and/or within the first and second substrates. The term “cavity,” as used herein, refers to the three-dimensional space bounded at least in part by interior surfaces of the first and second substrates after bonding, while “channel” refers either to the sometimes U-shaped floor created in the first and/or second substrates, or to the individually-addressable channels formed in the aforementioned substrate floor.

In some embodiments, selectively removing the photoresist to expose portions of the first substrate includes selectively removing the photoresist using nano-imprinting. In some of such embodiments, using nano-imprinting includes providing a mold with a patterned array of nano-pillars and pressing the mold into the layer of photoresist on the first substrate such that, after curing of the photoresist and separating the mold from the photoresist, the array of nano-pillars imprints a corresponding array of impressions in the photoresist.

The first material may be one or more of a primary amine-presenting organophosphate, an epoxy-presenting organophosphate, an unsaturated group containing organophosphate, a primary amine-presenting silane, an epoxy-presenting silane, or an unsaturated group containing silane. Some embodiments of the method include placing a bifunctional linker in one or more of the array of nano-wells (e.g., when the first material is a primary amine-presenting silane or a primary amine-presenting organophosphate). The bifunctional linker may be BS3 or an amine reactive polymer.

The second material may be one or more of a polyethylene-glycol-presenting silane, a polyethylene-glycol-presenting organophosphate, or poly(vinylphosphonic) acid. Bonding the second substrate to the first substrate may include bonding the first and second substrates using one or more of a glue, a UV-curable glue, a polymer tape, or a pressure-sensitive tape. In some embodiments, bonding the second substrate to the first substrate includes using laser-assisted bonding, wherein a bonding layer (e.g., of metal or metal oxide) is disposed between the first and second substrates.

Some embodiments of the present disclosure provide a method of making a microfluidic device. The method can include the steps of depositing a layer of metal oxide onto a first substrate, depositing a layer of photoresist over the metal oxide layer, selectively removing the photoresist to expose portions of the metal oxide layer under the photoresist layer, and etching the exposed portions of the metal oxide layer to form an array of nano-wells. The method further can include depositing a layer of a first material such that each nano-well in the array of nano-wells is coated with the first material. The first material can be configured to increase binding of DNA, proteins, and/or polynucleotides to the metal oxide. The method also can include depositing a layer of a second material on interstitial areas between the nano-wells. The second material can be configured to inhibit the binding of DNA, proteins, and/or polynucleotides to the interstitial areas. Further, the method can include bonding a second substrate to the first substrate to enclose the array of nano-wells in a cavity between and/or within the first and second substrates.

In some embodiments, selectively removing the photoresist to expose portions of the first substrate includes selectively removing the photoresist using nano-imprinting. In some of such embodiments, using nano-imprinting includes pressing a mold with a patterned array of nano-pillars into the layer of photoresist on the first substrate such that, after curing of the photoresist and separating the mold from the photoresist, the array of nano-pillars imprints a corresponding array of impressions in the photoresist.

The first material may be one or more of a primary amine-presenting organophosphate, an epoxy-presenting organophosphate, an unsaturated group containing organophosphate, a primary amine-presenting silane, an epoxy-presenting silane, or an unsaturated group containing silane. Some embodiments of the aforementioned method include placing a bifunctional linker in one or more of the array of nano-wells (e.g., when the first material is a primary amine-presenting silane or a primary amine-presenting organophosphate). The bifunctional linker may be BS3 or an amine reactive polymer.

The second material may be one or more of a polyethylene-glycol-presenting silane, a polyethylene-glycol-presenting organophosphate, or poly(vinylphosphonic) acid. Bonding the second substrate to the first substrate may include bonding the first and second substrates using one or more of a glue, a UV-curable glue, apolymer tape, or a pressure-sensitive tape. In some embodiments, bonding the second substrate to the first substrate comprises using laser-assisted bonding, wherein a bonding layer (e.g., of metal or metal oxide) is disposed between the first and second substrates.

Some embodiments of the present disclosure provide a microfluidic device. The microfluidic device can include a first substrate having a first patterned array of nano-wells on a first interior surface and a peripheral surface portion, and a second substrate having a channel and a side wall with an end surface. The end surface of the second substrate can be bonded to the peripheral surface portion of the first substrate, such that the first and second interior surfaces define a hermetic cavity within the bonded first and second substrates.

In some embodiments, the second substrate has a second patterned array of nano-wells on the second interior surface. The second patterned array of nano-wells can be made using nanosphere lithography or another suitable process. The first patterned array of nano-wells or the second patterned array of nano-wells may be disposed within one or more channels in the first or second interior surfaces. The first substrate can have a base made from glass, glass ceramics, silicon, or silica. Additionally, or alternatively, the second substrate can be made of glass, glass ceramics, or pure silica. In some embodiments, the first substrate and/or the second substrate can be made from transparent glass ceramics. In some embodiments, deposited on a surface of the base is an oxide layer (e.g., silicon dioxide, titanium dioxide, or aluminum oxide).

Some embodiments of the present disclosure provide a microfluidic device. The microfluidic device can have a first substrate with a first patterned array of nano-wells on a first interior surface and a peripheral surface portion, and a second substrate with a second interior surface and a side wall with an end surface. The end surface of the second substrate can be bonded to the peripheral surface portion of the first substrate such that the first and second interior surfaces define a hermetic cavity within the bonded first and second substrates.

In some embodiments, the second substrate has a second patterned array of nano-wells on the second interior surface. The first patterned array of nano-wells or the second patterned array of nano-wells may be disposed within one or more channels in the first or second interior surface. The first substrate can have a base made from glass, glass ceramics, silicon, or silica. A metal oxide layer can be deposited on a surface of the base. The metal oxide deposited may be one or more of SiO₂, Al₂O₃, ZnO₂, Ta₂O₅, Nb₂O₅, SnO₂, In₂O₃, TiO₂(e.g., a-TiO₂, r-TiO₂), indium tin oxide, indium zinc oxide, and ZrO₂.

In some embodiments, the second substrate has a second patterned array of nano-wells on the second interior surface. The first patterned array of nano-wells and/or the second patterned array of nano-wells may be disposed within one or more channels in the first or second interior surfaces. In some embodiments, the depth of the one or more channels is from 40 micrometers to 500 micrometers.

Some embodiments of the microfluidic device include an inlet at one end of the first or second substrate and an outlet at another end of the first or second substrate opposite the first end. The thickness of the metal oxide film may be in a range from one nanometer to 500 nanometers. In some embodiments, the metal oxide film is transparent to light with wavelengths in a range from 400 nanometers to 750 nanometers.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

The accompanying drawings incorporated in and forming a part of the specification illustrate several aspects of the present disclosure. In the drawings:

FIG. 1 is a schematic drawing showing a patterned microfluidic device with two individually-addressable channels, constructed in accordance with exemplary embodiments;

FIGS. 2A and 2B are schematic drawings showing a side view along the channel direction of two one-sided patterned flow cells, wherein the top and bottom substrates are bound together differently, according to exemplary embodiments;

FIG. 3 is a schematic drawing showing a side view along the channel direction of three two-sided patterned flow cells, wherein the top and bottom substrates are bound together via a tape, in accordance with exemplary embodiments;

FIG. 4 is a flow chart illustrating an exemplary process used to make patterned microfluidic devices, in accordance with exemplary embodiments;

FIGS. 5A-5D show representative scanning electron microscopic images of the nano-patterned substrates at different steps of nano-imprinting process, in accordance with exemplary embodiments;

FIGS. 6A and 6B show representative scanning electron microscopic images of two types of nano-patterned surfaces, according to exemplary embodiments.

While certain preferred embodiments will be disclosed hereinbelow, there is no intent to be limited to those embodiments. On the contrary, the intent is to cover all alternatives, modifications and equivalents as included within the spirit and scope of the disclosure as defined by the appended claims.

### DETAILED DESCRIPTION

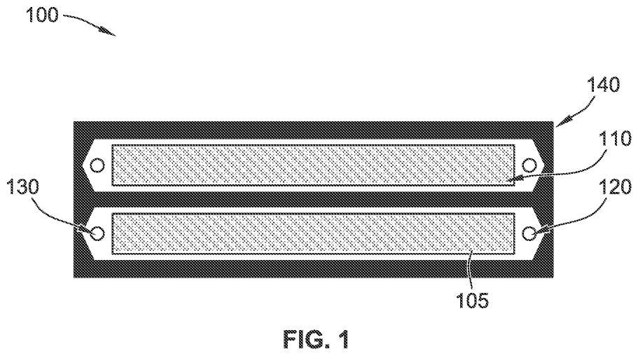

FIG. 1 is a schematic drawing showing a patterned flow cell 100 comprising two individually-addressable channels 105. On at least one channel surface of each channel 105, there is a patterned surface 110, an inlet port 120, and an outlet port 130, each of which can be on the same or different surfaces. The black region 140 shows an area at which two substrates of the flow cell are bound together to form hermetic seal.

In some embodiments, a patterned microfluidic device has a patterned surface with two distinct chemistries. In some embodiments, the patterned microfluidic device includes at least one channel For example, the patterned microfluidic device includes multiple individually-addressable channels 105. For instance, as shown in FIG. 1, the patterned microfluidic device 100 includes two individually-addressable channels 105. At least one surface of a channel 105 can include patterned DNA-binding regions and non-binding regions 110. In some embodiments, the microfluidic device also includes an inlet port 120 and an outlet port 130 for each channel 105. The channel 105 and inlet/outlet ports 120, 130 can be made on the patterned substrate or on another substrate.

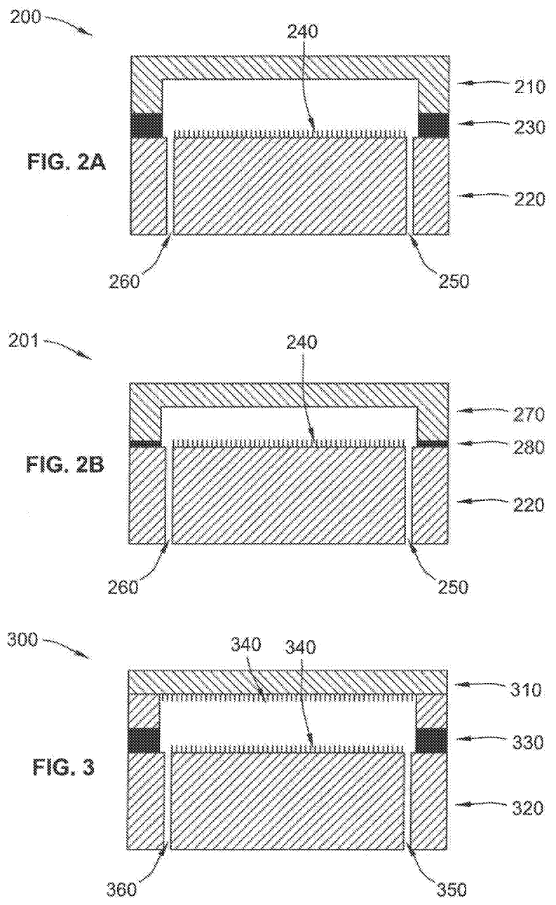

In some embodiments, the microfluidic device is a one-sided patterned flow cell device that has a surface including two distinct chemistries. For instance, as shown in FIG. 2A, the one-sided patterned flow cell device 200 includes a top substrate 210 and a bottom substrate 220 that are bound together via a tape 230. The top substrate 210 can have a channel and a side wall with an end surface. The bottom substrate 220 can include a patterned nano-well array 240, an inlet 250 and an outlet 260. In other embodiments, the top substrate 210 can be flat. In some of such embodiments, the tape 230 acts as a spacer to at least partially define the height of the channel

In some embodiments as shown in FIG. 2B, the one-sided patterned flow cell device 201 includes a top substrate 270 and a bottom substrate 220. The top substrate 270 includes an etched channel and a side wall with an end surface. Additionally, or alternatively, the bottom substrate 220 includes a patterned nano-well array 240, an inlet 250, and an outlet 260. The top and bottom substrates 270, 220 can be bound together to form a hermetic seal via a bonding layer 280 on the end surface of the side wall of the top substrate 270.

In some embodiments, the bonding layer 280 can comprise a metal. The metal can comprise one or more of gold, chromium, titanium, nickel, copper, zinc, cerium, lead, iron, vanadium, manganese, magnesium, germanium, aluminum, tantalum, niobium, tin, indium, cobalt, tungsten, ytterbium, zirconium, or an appropriate combination, or an oxide thereof. For example, an appropriate combination is a known alloy of these metals, or metal oxide, for instance, indium tin oxide or indium zinc oxide. In some embodiments, the bonding layer 280 is first deposited onto the top substrate 270, followed by protection (e.g., with photoresist or an etchant-resistant polymer tape), and finally etching to form a channel The bonding may be achieved via a laser-assisted ambient temperature bonding process. In some embodiments, the bonds can be laser bonds, for example, as described in United States Pat. Nos. 9,492,990, 9,515,286, and/or 9,120,287, the entirety of which are incorporated herein by reference.

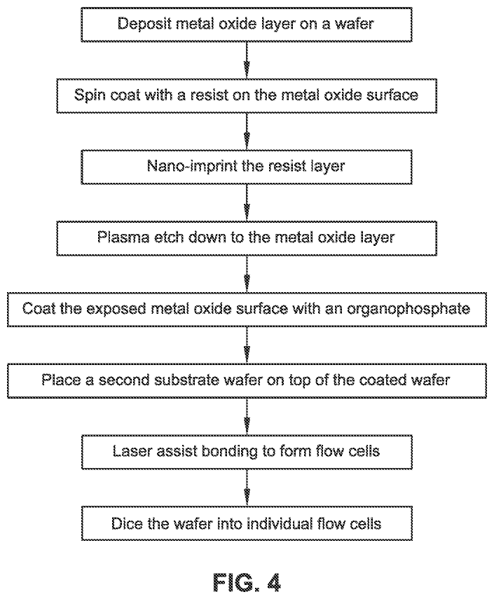

In some embodiments, the microfluidic device is a two-sided patterned flow cell device that has a surface including two distinct chemistries on each of the two surfaces (e.g., upper and lower surfaces, or ceiling and floor surfaces) of the channel For instance, as shown in FIG. 3, the two-sided patterned flow cell device 300 includes a top substrate 310 and a bottom substrate 320, both including patterned nano-well arrays 340 that are bound together via a tape 330. In some of such embodiments, the tape 330 acts as a spacer to at least partially define the height of the channel (e.g., when the top substrate 310 is flat). Additionally, or alternatively, the bottom substrate 320 includes an inlet 350 and an outlet 360. The tape 330 can be a polymer-carbon black composite film, a double-sided pressure adhesive tape, a double-sided polyimide tape, or another suitable tape. In some embodiments, the top substrate 310 can include patterned nano-wells 340 on the channel floor surface and have side wall with an end surface, and the tape 330 together with the side wall can define the height of the channel formed after bonding.

In some embodiments, the substrate (e.g., the first substrate and/or the second substrate) is made of (e.g., comprises, consists of, or consists essentially of) glass, glass ceramics, silica or silicon. Additionally, or alternatively, the substrate is substantially flat. In some embodiments, the substrate surface includes two distinct regions, one region having a first coating that promotes binding to DNA, proteins, and/or polynucleotides, and another region having a second coating that prevents binding to DNA, proteins, and/or polynucleotides. For instance, once the surface of the substrate is directly patterned using nano-imprinting, for example, the regions exposed, for example, via plasma etching are first coated with a primary amine-presenting silane or an epoxy-presenting silane or an unsaturated group including silane as the first coating. After removal of the remaining photoresist, the previously non-exposed and photoresist-protected regions can be coated with a polyethylene glycol (PEG)-presenting silane as the second coating.

DNA can selectively bind to the regions having the first coating (e.g., via either electrostatic interaction or covalent binding with or without a bifunctional linker). For example, when the first coating is an epoxy presenting silane, amine-terminated DNA can be directly coupled to the surface. When the first coating is an amine-presenting silane, DNA nanoballs can be directly immobilized on the surface via electrostatic interaction, while amine-terminated DNA can be coupled to the surface via a bifunctional linker such as BS3 (bis(sulfosuccinimidyl)suberate), or an amine-reactive polymer (e.g., polyethylene-alt-maleic anhydride).

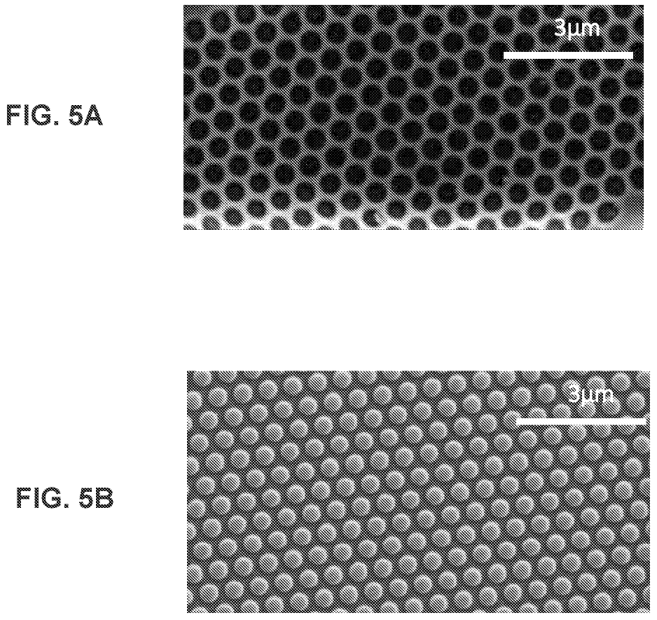

In some embodiments, the substrate includes a metal oxide layer, wherein the metal oxide layer surface includes two distinct regions, one region having a first coating that promotes binding to DNA, proteins, and/or polynucleotides, and another region having a second coating that prevents binding to DNA, proteins, and/or polynucleotides. For example, as shown in the flow chart of FIG. 4, a layer of metal oxide can be first deposited onto a flat wafer, followed by deposition of a layer of photoresist. The photoresist can be nano-imprinted and etched (e.g., by exposure to plasma etching), whereby the imprinted regions are exposed. Following the etching, non-exposed regions of the metal oxide layer can remain covered by the photoresist. The exposed metal oxide regions can be first coated with a primary amine presenting organophosphate or an epoxy presenting organophosphate or an unsaturated group containing organophosphate as the first coating. The remaining photoresist can be removed (e.g., to expose the previously non-exposed regions of the metal oxide layer), and the previously non-exposed and photoresist-protected regions can be coated with a polyethylene glycol (PEG)-presenting silane or organophosphate, or poly(vinylphosphonic acid) as the second coating.

DNA can selectively bind to the regions having the first coating (e.g., via either electrostatic interaction or covalent binding with or without a bifunctional linker). For example, when the first coating is an epoxy-presenting organophosphate, amine-terminated DNA can be directly coupled to the surface. When the first coating is an amine-presenting organophosphate, DNA nanoballs can be directly immobilized on the surface via electrostatic interaction, while amine-terminated DNA can be coupled to the surface via a bifunctional linker such as BS3 (bis(sulfosuccinimidyl)suberate), or an amine-reactive polymer (e.g., polyethylene-alt-maleic anhydride).

In some embodiments, the substrate is first patterned with a metal oxide using photolithography or nano-imprinting, so that the metal oxide region is coated with a first coating, followed by coating the non-metal oxide regions with a second coating. The first coating can be an organophosphate. Additionally, or alternatively, the second coating can be a silane. The metal oxide patterning can be made via either lift-off approach or reactive ion etching approach.

In some embodiments, the substrate is first coated with a photoresist, followed by patterning to form an array of nano-wells using photolithography or nanoimprinting in combination with reactive ion etching, depositing a layer of metal oxide, and finally lifting off the photoresist, so that the bottom and sidewall of all nano-wells are coated with the metal oxide. Following the photoresist lift off, the top surface of the substrate (e.g., the portion of the substrate surface disposed between the nano-wells) can be a bare substrate surface (e.g., uncoated by the metal oxide). Afterwards, the metal oxide regions can be coated with a first coating such as an organophosphate. Additionally, or alternatively, the top substrate surface can be coated with a second coating such as a silane. The metal oxide coating inside the nano-wells can provide a dielectric layer to enhance fluorescence. Furthermore, when the size of the nano-wells is reduced by the metal oxide to less than 100 nanometers, such small nano-wells can enable a physical confinement to substantially enhance fluorescence. In addition, the metal oxide coating inside the nano-wells can facilitate in situ UV-radiation-enabled polymerization, and thus DNA capture and amplification (e.g., as disclosed in U.S. Patent Pub. No. 2014/0329723A1, entitled, “Patterned Flow Cells Useful for Nucleic Acid Analysis,” which is incorporated, herein by reference, in its entirety).

The metal oxide can include one or more of Al₂O₃, ZnO₂, Ta₂O₅, Nb₂O₅, SnO₂, MgO, indium tin oxide, CeO₂, CoO, Co₃O₄, Cr₂O₃, Fe₂O₃, Fe₃O₄, In₂O₃, Mn₂O₃, NiO, a-TiO₂ (anatase), r-TiO₂ (rutile), WO₃, Y₂O₃, ZrO₂, or other metal oxides. In some embodiments, the metal oxide is transparent to light within a visible wavelength (e.g., from 400 nanometers to 750 nanometers or from 450 nanometers to 750 nanometers). For example, the metal oxide can have a transmission to light within a visible wavelength of 50%, 60%, 70%, 80%, 90%, 95%, 99%, 100%, or any ranges defined by the listed values.

Besides surface patterning, fiducial marks can be made together with a repeating pattern of features using photolithography and/or nanoimprinting. Such fiducial marks can be used as synchronous track or registering features for sequencing imaging (e.g., as disclosed in U.S. Patent Pub. No. 2014/0085457 A1, entitled “Method of fabricating patterned functional substrates,” or U.S. Patent Pub. No. 2015/0125053A1, entitled “Image Analysis Useful for Patterned Objects,” each of which is incorporated herein by reference in its entirety).

The nano-patterning can be made via photolithography. For example, to create a suitable substrate, a glass wafer was coated with a 600 nm SiO₂layer using plasma-enhanced chemical vapor deposition (PECVD). After coating with a layer of photoresist, the photoresist was patterned, for example with UV light. After pattern exposure, reactive ion etching was used to fabricate a nano-well substrate including nano-wells with a depth of 300 nm, a diameter of 400 nm, and a pitch of 650 nm. Afterwards, a 50 nm Al₂O₃ layer was deposited onto the nano-well substrate, followed by lifting off the photoresist. The resultant Al₂O₃-coated nano-wells may be further coated with a material, such as 3-aminopropylphosphate, to form DNA-binding regions. Finally, the interstitial SiO₂surfaces between nano-wells (e.g., an interstitial portion of the substrate exposed by lifting off the photoresist) may be coated with an mPEG5K-silane to form a DNA non-binding surface.

In some embodiments, nano-imprinting can be used for making nano-patterning. For example, a nanoimprint mold can be fabricated from a nano-well glass wafer master made by conventional photolithography. The nano-well master may first be cleaned by oxygen plasma and coated with (tridecafluoro-1,1,2,2-tetrahydrooctyl) trichlorosilane under vacuum as a release agent. The mold resin can be made from perfluoropolyether (PFPE) and a photo-initiator. The mold resin can be directly cast on the nano-well master and then a polyethylene terephthalate film (PET) placed on top of the mold resin.

After curing under 365 nm UV-LED light at a dose of 3000 mJ/cm² in an inert nitrogen environment, the nano-well mold can be released from the nano-well master. The mold material is not limited to PFPE materials, and other fluorinated materials (e.g., ethylene tetrafluoroethylene (ETFE), Teflon, etc.) as well as others like silicone (e.g., polydimethylsiloxane PDMS), polycarbonate, polyurethane acrylate (PUA), can also be used.

The substrates used for nano-well fabrication can be made of a glass wafer that is pre-coated with different oxide layers, including for example 600 nm of SiO₂, 70 nm of TiO₂or 50 nm of Al₂O₃. A chemically-amplified, epoxy-based negative photoresist may be diluted with cyclopentanone solvent at the ratio of 1:10 in weight to reduce the coating thickness for the nano-imprinting application. Prior to photoresist coating, the substrate can be cleaned with acetone and isopropanol and then baked at 150° C. for five minutes, and then a thin layer (˜13 nm) of a photoresist stripper can be spin-coated onto the substrate (e.g., to enable the later removal of the photoresist). After spin-coating, the stripper layer can be baked on a 200° C. hotplate for one minute and then cooled down to room temperature. Photoresist dilution may be spin-coated on top of the stripper layer at the spinning speed of 3,000 rpm for 45 seconds and then baked at 65° C. for one minute and 95° C. for one minute to form a photoresist film with thickness of approximately 177 nm.

The nanoimprint process can be performed using a nano-imprinter. After laying the nano-imprint mold on top of the photoresist, the stack may be imprinted at 80 psi pressure at a temperature of 90° C. for four minutes and then exposed under 365 nm UV-LED light at a dose of 300 mJ/cm², followed by baking at 65° C. for one minute and at 95° C. for one minute. Finally, the nano-imprint mold can be peeled off from the substrate to expose the nano-well structures. The etching step for a substrate surface may be performed in a plasma etcher under the following conditions: 100 W, 80 sccm's O₂, 150 mTorr for 72 seconds at the etching rate of 1.39 nm/sec.

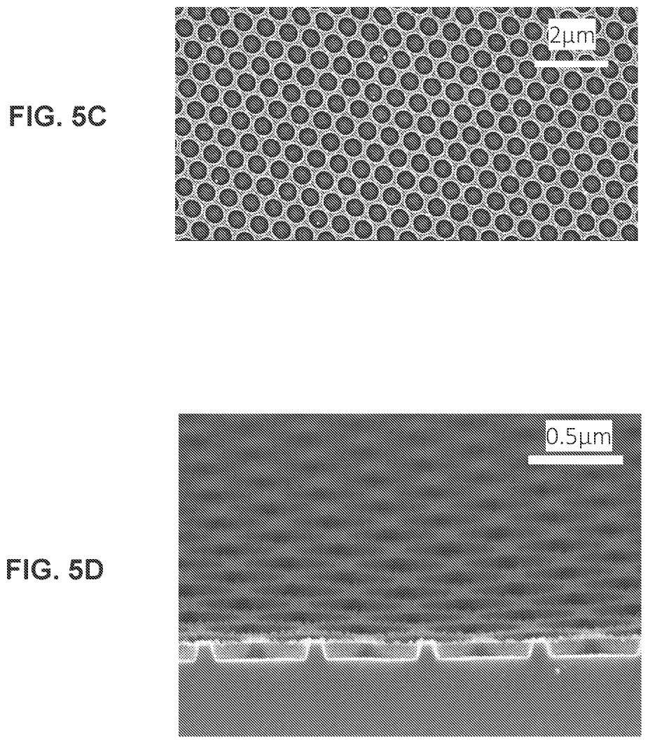

FIGS. 5A-5D show representative scanning electron microscopic images of nano-patterned substrates at different steps of an exemplary nano-imprinting process: (5A) a master wafer including an array of nano-wells; (5B) a silicone stamp including an array of nano-pillars after replicated from the master; (5C) an imprinted structure on a UV-curable photoresist layer deposited on a glass wafer; and (5D) a reactive ion etched nano-well array on the glass wafer after nano-imprinting.

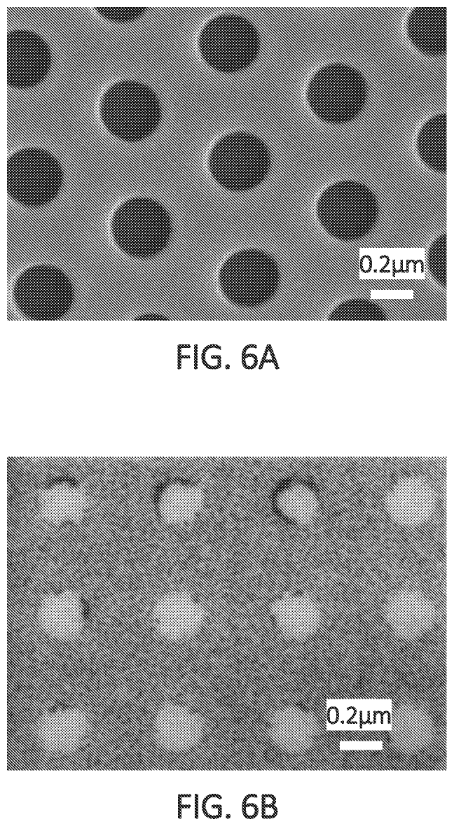

After nano-imprinting, follow-up reactive ion etching may be used to generate nano-well structures within the substrate (see FIG. 5A) or obtain patterned chemistry (as patterned aminopropylsilane patches as showed in FIG. 5B). FIGS. 6A and 6B show representative scanning electron microscopic images of two types of nano-patterned surfaces: (6A) a nano-well array; (6B) a patterned aminopropyltrimethoxysilane surface.

All references, including publications, patent applications, and patents cited herein are hereby incorporated by reference to the same extent as if each reference were individually and specifically indicated to be incorporated by reference and were set forth in its entirety herein.

The use of the terms “a” and “an” and “the” and similar referents in the disclosure (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosed embodiments. No language in the specification should be construed as indicating any non-claimed element as essential.

It will be apparent to those skilled in the art that various modifications and variations can be made without departing from the spirit or scope of the disclosed embodiments. Since modifications, combinations, sub-combinations and variations of the disclosed embodiments incorporating the spirit and substance of the embodiments may occur to persons skilled in the art, the disclosed embodiments should be construed to include everything within the scope of the appended claims and their equivalents.

1. A method of making a microfluidic device, the method comprising the steps of:
depositing a layer of photoresist onto a first substrate;
selectively removing a portion of the photoresist to expose portions of the first substrate under the photoresist layer;
etching the exposed portions of the first substrate to form an array of nano-wells;
depositing a metal oxide layer over the photoresist such that each nano-well in the array of nano-wells is coated with a metal oxide;
depositing a layer of a first material over the metal oxide layer such that each nano-well in the array of nano-wells is coated with the first material to increase binding of at least one of DNA, proteins, or polynucleotides to the metal oxide;
depositing a layer of a second material on interstitial areas of the first substrate between the nano-wells to inhibit the binding of at least one of DNA, proteins, or polynucleotides to the interstitial areas; and
bonding a second substrate to the first substrate to enclose the array of nano-wells in a cavity between the first and second substrates.

2. The method of claim 1, wherein selectively removing the photoresist to expose portions of the first substrate comprises pressing a mold comprising a patterned array of nano-pillars into the layer of photoresist on the first substrate such that, after curing of the photoresist and separating the mold from the photoresist, the array of nano-pillars imprints a corresponding array of impressions in the photoresist.

3. The method of claim 1, comprising removing a remaining portion of the photoresist before or after depositing the layer of the first material.

4. The method of claim 1, wherein the first material comprises at least one of a primary amine-presenting organophosphate, an epoxy-presenting organophosphate, an unsaturated group containing organophosphate, a primary amine-presenting silane, an epoxy-presenting silane, or an unsaturated group containing silane.

5. The method of claim 4, comprising depositing a bifunctional linker in one or more of the array of nano-wells, wherein the first material comprises a primary amine-presenting silane or a primary amine-presenting organophosphate.

6. The method of claim 5, wherein the bifunctional linker comprises BS3 or an amine reactive polymer.

7. The method of claim 1, wherein the second material comprises at least one of a polyethylene-glycol-presenting silane, a polyethylene-glycol-presenting organophosphate, or poly(vinylphosphonic) acid.

8. The method of claim 1, wherein bonding the second substrate to the first substrate comprises bonding the first and second substrates using one of a glue, a UV-curable glue, a polymer tape, or a pressure-sensitive tape.

9. The method of claim 1, wherein bonding the second substrate to the first substrate comprises bonding the first and second substrates using laser-assisted bonding, wherein a bonding layer of a metal or a metal oxide is disposed between the first and second substrates.

10. A method of making a microfluidic device, the method comprising the steps of:
depositing a metal oxide layer onto a first substrate;
depositing a layer of photoresist over the metal oxide layer;
selectively removing a portion of the photoresist to expose portions of the metal oxide layer under the photoresist layer;
etching the exposed portions of the metal oxide layer to form an array of nano-wells;
depositing a layer of a first material such that each nano-well in the array of nano-wells is coated with the first material to increase binding of at least one of DNA, proteins, or polynucleotides to the first substrate;
removing a remaining portion of the photoresist;
depositing a layer of a second material on interstitial areas of the first substrate between the nano-wells to inhibit the binding of at least one of DNA, proteins, or polynucleotides to the interstitial areas; and
bonding a second substrate to the first substrate to enclose the array of nano-wells in a cavity between the first and second substrates.

11. The method of claim 10, wherein selectively removing the photoresist comprises pressing a mold comprising a patterned array of nano-pillars into the layer of photoresist on the first substrate so that, after curing of the photoresist and separating the mold from the photoresist, the array of nano-pillars imprinting an array of nano-wells in the photoresist.

12. The method of claim 10, wherein the first material comprises at least one of a primary amine-presenting organophosphate, an epoxy-presenting organophosphate, an unsaturated group containing organophosphate, a primary amine-presenting silane, an epoxy-presenting silane, or an unsaturated group containing silane.

13. The method of claim 12, comprising depositing a bifunctional linker in one or more of the array of nano-wells, wherein the first material is a primary amine-presenting silane or a primary amine-presenting organophosphate.

14. The method of claim 10, wherein the second material comprises at least one of a polyethylene-glycol-presenting silane, a polyethylene-glycol-presenting organophosphate, or poly(vinylphosphonic) acid.

15. The method of claim 10, wherein bonding the second substrate to the first substrate comprises bonding the first and second substrates using one of a glue, a UV-curable glue, a polymer tape, a pressure-sensitive tape, or laser-assisted bonding.

16. A microfluidic device comprising:
a first substrate comprising a first patterned array of nano-wells on a first interior surface and a peripheral surface portion;
a second substrate comprising a second interior surface and a side wall with an end surface;
wherein the end surface of the second substrate is bonded to the peripheral surface portion of the first substrate such that the first and second interior surfaces define a hermetic cavity within the bonded first and second substrates.

17. The microfluidic device of claim 16 wherein the second substrate comprises a second patterned array of nano-wells on the second interior surface.

18. The microfluidic device of claim 17, wherein the first patterned array of nano-wells or the second patterned array of nano-wells is disposed within one or more channels in the first or second interior surface.

19. The microfluidic device of claim 16, wherein the first substrate comprises a base comprising glass, glass ceramic, silicon, or silica having deposited on its surface a layer of silicon dioxide or metal oxide.

20. The microfluidic device of claim 16, comprising a metal oxide layer disposed on the first interior surface or the second interior surface, wherein the metal oxide layer is transparent to light with wavelengths in a range from 400 nanometers to 750 nanometers.

21-25. (canceled)
